(19) United States
(12) Patent Application Publication
(10) Pub. No.: US 2010/0207139 A1
(43) Pub. Date: Aug. 19, 2010

(54) PHOTONIC MATERIAL HAVING REGULARLY ARRANGED CAVITIES

(76) Inventors: Holger Winkler, Darmstadt (DE); Helmut Bechtel, Roetgen (DE); Thomas Juestel, Witten (DE); Joachim Opitz, Aachen (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 12/063,362

(22) PCT Filed: Jul. 17, 2006
(86) PCT No.: PCT/EP06/06993

§ 371 Date: Feb. 8, 2008

(30) Foreign Application Priority Data
Aug. 11, 2005 (EP) 05017485.3

(51) Int. Cl. H01L 33/44; H01L 33/30; H01L 33/00; B32B 3/26; B29C 67/20; B05D 3/02

(52) U.S. Cl. 257/98; 257/103; 438/29; 428/304.4; 428/317.9; 264/41; 427/372.2; 257/E33.023; 257/E33.061; 257/E33.067

(57) ABSTRACT

The invention relates to photonic materials having regularly arranged cavities containing at least one colorant, where the wall material of the photonic material has dielectric properties and as such is essentially non-absorbent for the wavelength of an absorption band of the respective colorant and is essentially transparent for the wavelength of a colorant emission which can be stimulated by the absorption wavelength, and the cavities are shaped in such a way that radiation having the wavelength of the weak absorption band of the colorant is stored in the photonic material, to the use thereof as phosphor system in an illuminant, to corresponding illuminants and production processes.

The invention relates to photonic materials, to the use thereof as phosphor system in an illuminant, to corresponding illuminants and production processes.

Some attempts to produce white-light illumination systems with light-emitting diodes as radiation sources have recently been made.

A first design of white light-emitting illumination systems using light-emitting diodes (LEDs) is based on combinations of LEDs which emit visible light. In these systems, at least two LEDs (for example blue and yellow) or three LEDs (for example red, blue and green) are combined with one another. The visible light from the various LEDs mixes to give a whitish light (“digital white light”). The generation of white light having a desired tint through an arrangement of red, green and blue LEDs is, however, virtually impossible owing to long-term changes in the diodes with respect to hue, luminance and other factors. Complex control electronics are necessary for compensation of these differential ageing effects and the colour shifts of each LED.

In order to solve these problems, illumination systems of a second design, in which the colour of the LED radiation is converted into visible white light (“analogue white light”) by luminescent phosphors have already been developed.

White-light illumination systems of this type with converter phosphors are based, in particular, on two approaches: either on the trichromatic RGB approach, in which the colours red, green and blue are mixed, where the blue component of the light emission can be generated by a phosphor and/or can originate from the primary emission from an LED, or on a second, simpler solution, the dichromatic BY approach, in which the colours yellow and blue are mixed, where the yellow component of the light emission can originate from a yellow light-emitting phosphor and the blue component can originate from a phosphor or the primary emission of a blue LED. This phosphor converter system is the most frequently employed.

In particular, a blue light-emitting diode comprising a semiconductor material based on AlInGaN with a Y₃Al₅O₁₂:Ce (YAG-Ce³⁺) garnet as phosphor is employed in the dichromatic approach in accordance with, for example, U.S. Pat. No. 5,998,925. The YAG-Ce³⁺ phosphor is applied as coating to the AlInGaN LED, and a part of the blue light emitted by the LED is converted into yellow light by the phosphor. Another part of the blue light emission from the LED passes through the phosphor. This system thus emits blue light from the LED and yellow light from the phosphor. The superimposition of the blue and yellow emission bands is perceived by an observer as white light having a typical colour reproduction index CRI of about 75 and a colour temperature Tc of about 6000 to about 8000 K.

After advances in light-emitting diode technology recently, very efficient light-emitting diodes are now available which emit from the near UV to the blue region of the electromagnetic spectrum. Numerous coloured and white light-emitting LEDs comprising converter phosphors are therefore available on the market today which are becoming a competitor to conventional incandescent and fluorescent lamps.

U.S. Pat. No. 6,734,465 discloses nanocrystalline phosphors and photonic structures for solid-state light sources. U.S. Pat. No. 6,734,465 discloses a photonic structure for the emission of white light on excitation by an LED, which comprises the following: a) a radiation-emitting diode; b) an optically transparent matrix material which is arranged in the ray path of the light emitted by the said diode; and c) nanocrystalline phosphors which are dispersed in the said matrix material and emit light after excitation by radiation from the diode.

The provision of luminescent materials for such applications is difficult since there are only few luminescent materials having an absorption spectrum in the near UV and in the blue part of the electromagnetic spectrum which are able to convert efficiently the said near-UV and blue light into visible coloured or white light and are at the same time also stable in the long term.

In particular for optimisation of the colour temperature of such light-emitting diodes with white light, it would be desirable to be able to employ additional emitters in the red spectral region. However, it has to date not been possible to employ the known converters, such as Y₂O₃:Eu, in the light-emitting diodes since their red emission cannot be excited by means of the blue light from the indium gallium nitride emitters.

Surprisingly, it has now been found that it is also possible to utilise weak absorption bands of a colorant for excitation if the colorant is present in a photonic material having regularly arranged cavities.

The present invention therefore relates firstly to a photonic material having regularly arranged cavities containing at least one colorant, where the wall material of the photonic material has dielectric properties and as such is essentially non-absorbent for the wavelength of an absorption band of the respective colorant and is essentially transparent for the wavelength of a colorant emission which can be stimulated by the absorption wavelength, and the cavities are shaped in such a way that radiation having the wavelength of the weak absorption band of the colorant is stored in the photonic material.

Photonic materials comprising arrangements of cavities having an essentially monodisperse size distribution in the sense of the present invention are materials which have three-dimensional photonic structures. Three-dimensional photonic structures are generally taken to mean systems which have a regular, three-dimensional modulation of the dielectric constant (and consequently also of the refractive index). If the periodic modulation length corresponds approximately to the wavelength of the (visible) light, the structure interacts with the light in the manner of a three-dimensional diffraction grating, which is evident from angle-dependent colour phenomena.

The inverse structure to the opal structure (=arrangement of cavities having an essentially monodisperse size distribution) is thought to be formed by regular spherical cavities being arranged in closest packing in a solid material. An advantage of inverse structures of this type compared with the normal structures is the formation of photonic band gaps with dielectric constant contrasts which are already much lower (K. Busch et al. Phys. Rev. Letters E, 198, 50, 3896).

Photonic materials having cavities must consequently have a solid wall. Suitable in accordance with the invention are wall materials which have dielectric properties and as such are essentially non-absorbent for the wavelength of an absorption band of the respective colorant and are essentially transparent for the wavelength of a colorant emission which can be stimulated by the absorption wavelength.

It is preferred in accordance with the invention for the wall material of the photonic material as such to allow at least 95%, preferably at least 97%, of the radiation having the wavelength of the absorption band of the colorant to pass through.

In a variant of the invention, the matrix essentially consists of a radiationstable organic polymer, which is preferably crosslinked, for example an epoxy resin. In another variant of the invention, the matrix around the cavities essentially consists of an inorganic material, preferably a metal chalcogenide or metal pnictide, where mention may be made, in particular, of silicon dioxide, aluminium oxide, zirconium oxide, iron oxides, titanium dioxide, cerium dioxide, gallium nitride, boron nitride, aluminium nitride, silicon nitride and phosphorus nitride, or mixtures thereof. It is particularly preferred in accordance with the invention for the wall of the photonic material to essentially consist of an oxide or mixed oxide of silicon, titanium, zirconium and/or aluminium, preferably of silicon dioxide.

Three-dimensional inverse structures, i.e. diffractive colorants having regular arrangements of cavities which are to be employed in accordance with the invention, can be produced, for example, by template synthesis:
Monodisperse spheres are arranged in closest sphere packing as structure-forming templates.
The cavities between the spheres are filled with a gaseous or liquid precursor or a solution of a precursor by utilising capillary effects.
The precursor is converted (thermally) into the desired material.
The templates are removed, leaving behind the inverse structure.

The literature discloses many such processes which can be utilised for the production of cavity structures for use in accordance with the present invention.

For example, SiO₂ spheres can be arranged in closest packing and the cavities filled with tetraethyl orthotitanate-containing solutions. After a number of conditioning steps, the spheres are removed using HF in an etching process, leaving behind the inverse structure of titanium dioxide (V. Colvin et al. Adv. Mater. 2001, 13, 180).

De La Rue et al. (De La Rue et al. Synth. Metals, 2001, 116, 469) describe the production of inverse opals consisting of TiO₂ by the following method: a dispersion of 400 nm polystyrene spheres is dried on a filter paper under an IR lamp. The filter cake is washed by sucking through ethanol, transferred into a glove box and infiltrated with tetraethyl orthotitanate by means of a water-jet pump. The filter paper is carefully removed from the latex/ethoxide composite, and the composite is transferred into a tubular furnace. Calcination in a stream of air is carried out in the tubular furnace at 575° C. for 8 h, causing the formation of titanium dioxide from the ethoxide and burning out the latex particles. An inverse opal structure of TiO₂ remains behind.

Martinelli et al. (M. Martinelli et al. Optical Mater. 2001, 17, 11) describe the production of inverse TiO₂ opals using 780 nm and 3190 nm polystyrene spheres. A regular arrangement in closest sphere packing is achieved by centrifuging the aqueous sphere dispersion at 700-1000 rpm for 24-48 hours followed by decantation and drying in air. The regularly arranged spheres are moistened with ethanol on a filter in a Büchner funnel and then provided dropwise with an ethanolic solution of tetraethyl orthotitanate. After the titanate solution has percolated in, the sample is dried in a vacuum desiccator for 4-12 hours. This filling procedure is repeated 4 to 5 times. The polystyrene spheres are subsequently burnt out at 600° C.-800° C. for 8-10 hours.

Stein et al. (A. Stein et al. Science, 1998, 281, 538) describe the synthesis of inverse TiO₂ opals starting from polystyrene spheres having a diameter of 470 nm as templates. These are produced in a 28-hour process, subjetted to centrifugation and air-dried. The latex templates are then applied to a filter paper. Ethanol is sucked into the latex template via a Büchner funnel connected to a vacuum pump. Tetraethyl orthotitanate is then added dropwise with suction. After drying in a vacuum desiccator for 24 h, the lattices are burnt out at 575° C. for 12 h in a stream of air.

Vos et al. (W. L. Vos et al. Science, 1998, 281, 802) produce inverse TiO₂ opals using polystyrene spheres having diameters of 180-1460 nm as templates. In order to establish closest packing of the spheres, a sedimentation technique is used supported by centrifugation over a period of up to 48 h. After slow evacuation in order to dry the template structure, an ethanolic solution of tetra-n-propoxy orthotitanate is added to the latter in a glove box. After about 1 h, the infiltrated material is brought into the air in order to allow the precursor to react to give TiO₂. This procedure is repeated eight times in order to ensure complete filling with TiO₂. The material is then calcined at 450° C.

Core/shell particles whose shell forms a matrix and whose core is essentially solid and has an essentially monodisperse size distribution are described in German patent application DE-A-10145450. The use of core/shell particles whose shell forms a matrix and whose core is essentially solid and has an essentially monodisperse size distribution as templates for the production of inverse opal structures and a process for the production of inverse opal-like structures using core/shell particles of this type are described in international patent application WO 2004/031102. The mouldings described having homogeneous, regularly arranged cavities (i.e. inverse opal structure) preferably have walls of metal oxides or of elastomers. Consequently, the mouldings described are either hard and brittle or exhibit an elastomeric character.

The removal of the regularly arranged template cores can be carried out in various ways. If the cores consist of suitable inorganic materials, they can be removed by etching. For example, silicon dioxide cores can preferably be removed using HF, in particular dilute HF solution. In this procedure, it may in turn be preferred for crosslinking of the wall material to be carried out before or after the removal of the cores.

If the cores in the core/shell particles are built up from a UV radiationdegradable material, preferably a UV-degradable organic polymer, the removal of the cores is carried out by UV irradiation. In this procedure too, it may in turn be preferred for crosslinking of the shell to be carried out before or after the removal of the cores. Suitable core materials are then, in particular, poly(tert-butyl methacrylate), poly(methyl methacrylate), poly(n-butyl methacrylate) or copolymers containing one of these polymers.

It may furthermore be particularly preferred for the degradable core to be thermally degradable and to consist of polymers which are either thermally depolymerisable, i.e. decompose into their monomers on exposure to heat, or for the core to consist of polymers which decompose on degradation to give low-molecular-weight constituents which are different from the monomers. Suitable polymers are given, for example, in the table “Thermal Degradation of Polymers” in Brandrup, J. (Ed.): Polymer Handbook. Chichester Wiley 1966, pp. V-6-V-10, all polymers which give volatile degradation products being suitable. The contents of this table are expressly part of the disclosure content of the present application.

Suitable thermally degradable polymers are, in particular,
poly(styrene) and derivatives, such as poly(α-methylstyrene) or poly(styrene) derivatives carrying substituents on the aromatic ring, such as, in particular, partially or perfluorinated derivatives,
poly(acrylate) and poly(methacrylate) derivatives as well as esters thereof, particularly preferably poly(methyl methacrylate) or poly(cyclohexyl methacrylate), or copolymers of these polymers with other degradable polymers, such as, preferably, styrene-ethyl acrylate copolymers or methyl methacrylate-ethyl acrylate copolymers,
polybutadiene and copolymers with other monomers mentioned here,
cellulose and derivatives, such as oxidised cellulose and cellulose triacetate,
polyketones, such as, for example, poly(methyl isopropenyl ketone) or poly(methyl vinyl ketone),
polyolefins, such as, for example, polyethylene and polypropylene, polyisoprene, polyolefin oxides, such as, for example, polyethylene oxide or polypropylene oxide, polyethylene terephthalate, polyformaldehyde, polyamides, such as nylon 6 and nylon 66, polyperfluoroglucarodiamidine, polyperfluoropolyolefins, such as polyperfluoropropylene and polyperfluoroheptene,
polyvinyl acetate, polyvinyl chloride, polyvinyl alcohol, polyvinylcyclohexanone, polyvinyl butyrate and polyvinyl fluoride.

Particular preference is given here to the use of poly(styrene) and derivatives, such as poly(α-methylstyrene) or poly(styrene) derivatives carrying substituents on the aromatic ring, such as, in particular, partially or perfluorinated derivatives, poly(acrylate) and poly(methacrylate) derivatives as well as esters thereof, particularly preferably poly(methyl methacrylate) or poly(cyclohexyl methacrylate), or copolymers of these polymers with other degradable polymers, such as, preferably, styrene-ethyl acrylate copolymers or methyl methacrylate-ethyl acrylate copolymers, and polyolefins, polyolefin oxides, polyethylene terephthalate, polyformaldehyde, polyamides, polyvinyl acetate, polyvinyl chloride or polyvinyl alcohol.

Regarding the description of the resultant mouldings and the processes for the production of mouldings, reference is made to the patent application WO 2004/031102, the corresponding disclosure content of which expressly also belongs to the contents of the present application.

It is particularly preferred in accordance with the invention for the average diameter of the cavities in the photonic material to be in the range from about 200-400 nm, preferably in the range from 250-380 nm.

In the corresponding processes, the mouldings of inverse opal are either obtained directly in powder form or can be comminuted by grinding. The resultant particles can then be processed further in the sense according to the invention.

The colorant or phosphor according to the invention preferably comprises nanoscale phosphor particles. The colorants here generally have a chemical composition comprising a host material and one or more dopants.

The host material can preferably comprise compounds from the group of the sulfides, selenides, sulfoselenides, oxysulfides, borates, aluminates, gallates, silicates, germanates, phosphates, halophosphates, oxides, arsenates, vanadates, niobates, tantalates, sulfates, tungstates, molybdates, alkali metal halogenates and other halides or nitrides. The host materials here are preferably alkali metal, alkaline-earth metal or rare-earth compounds.

The colorant here is preferably in nanoparticulate form. Preferred particles here have an average particle size of less than 50 nm, determined as the hydraulic diameter by means of dynamic light scattering, it being particularly preferred for the average particle diameter to be less than 25 nm.

In a variant of the invention, the light of blue light sources is to be supplemented by red components. In this case, the colorant in a preferred embodiment of the present invention is an emitter for radiation in the range from 550 to 700 nm. The preferred dopants here include, in particular, rare-earth compounds doped with europium, samarium, terbium or praseodymium, preferably with triply positively charged europium ions.

Furthermore, in accordance with an aspect of the present invention, the doping used comprises one or more elements from a group comprising elements from main groups 1a, 2a or Al, Cr, Tl, Mn, Ag, Cu, As, Nb, Ni, Ti, In, Sb, Ga, Si, Pb, Bi, Zn, Co and/or elements of the so-called rare-earth metals.

A mutually matched dopant pair, for example cerium and terbium, having good energy transfer can preferably be used, where appropriate per desired fluorescence colour, where the one acts as energy absorber, in particular as UV light absorber, and the other as fluorescent light emitter.

In particular, the material selected for the doped nanoparticles can comprise the following compounds, where in the following notation, the host compound is indicated to the left of the colon and one or more doping elements are indicated to the right of the colon. If chemical elements are separated from one another by commas and enclosed in parentheses, they can be used optionally. A first selection list is defined as follows, where, depending on the desired fluorescence property of the nanoparticles, one or more of the compounds provided for selection can be used:

LiI:Eu; NaI:Tl; CsI:Tl; Csl:Na; LiF:Mg; LiF:Mg,Ti; LIF:Mg,Na; KMgF₃:Mn; Al₂O₃:Eu; BaFCl:Eu; BaFCl:Sm; BaFBr:Eu; BaFCl_{0.5}Br_{0.5}:Sm; BaY₂F₆:A (A=Pr, Tm, Er, Ce); BaSi₂O₅:Pb; BaMg₂Al₁₆O₂₇:Eu; BaMgAl₁₄O₂₃:Eu; BaMgAl₁₀O₁₇:Eu; (BaMgAl₂O₄:Eu; Ba₂P₂O₇:Ti; (Ba, Zn, Mg)₃Si₂O₇:Pb; Ce(Mg, Ba) Al₁₁O₁₉; Ce_{0.65}Tb_{0.35}MgAl₁₁O₁₉; MgAl₁₁O₁₉:Ce,Tb; MgF₂:Mn; MgS:Eu; MgS:Ce; MgS:Sm; MgS(Sm, Ce); (Mg, Ca)S:Eu; MgSiO₃:Mn; 3.5MgO.0.5MgF₂GeO₂:Mn; MgWO₄:Sm; MgWO₄:Pb; 6MgOAs₂O₅:Mn; (Zn, Mg)F₂:Mn; (Zn, Be)SO₄Mn; Zn₂SiO₄:Mn; Zn₂SiO₄:Mn,As; ZnO:Zn; ZnO:Zn,Si,Ga; Zn₃(PO₄)₂:Mn; ZnS:A′ (A′=Ag, Al, Cu); (Zn, Cd)S:A″ (A″=Cu, Al, Ag, Ni); CdBO₄:Mn; CaF₂:Mn; CaF₂:Dy; CaS:A′″ (A″′=lanthanoids, Bi); (Ca, Sr)S:Bi; CaWO₄:Pb; CaWO₄:Sm; CaSO₄:A″″ (A″″=Mn, lanthanoids); 3Ca₃(PO₄)₂Ca(F, Cl)₂: Sb, Mn; CaSiO₃:Mn, Pb; Ca₂Al₂Si₂O₇:Ce; (Ca, Mg)SiO₃:Ce; (Ca, Mg)SiO₃:Ti; 2SrO6(B₂O₃)SrF₂:Eu; 3Sr₃ (PO₄)₂. CaCl₂: Eu; A₃(PO₄)₂. ACl₂:Eu (A=Sr, Ca, Ba); (Sr, Mg)₂P₂O₇:Eu; (Sr, Mg)₃(PO₄)₂:Sn; SrS:Ce; SrS:Sm, Ce; SrS:Sm; SrS:Eu; SrS:Eu,Sm; SrS:Cu,Ag; Sr₂P₂O₇: Sn; Sr₂P₂O₇:Eu; Sr₄Al₁₄O₂₅:Eu; SrGa₂S₄:A* (A*=lanthanoids, Pb); SrGa₂S₄:Pb; Sr₃Gd₂Si₆O₁₈:Pb,Mn; YF₃:Yb,Er; YF₃:Ln (Ln=lanthanoids); YLiF₄:Ln (Ln=lanthanoids); Y₃Al₅O₁₂:Ln (Ln=lanthanoids); YAl₃(BO₄)₃:Nd,Yb; (Y,Ga)BO₃:Eu; (Y,Gd)BO₃:Eu; Y₂Al₃Ga₂O₁₂:Tb; Y₂SiO₅:Ln (Ln=lanthanoids); Y₂O₃:Ln (Ln=lanthanoids); Y₂O₂S:Ln (Ln=lanthanoids); YVO₄:A (A=lanthanoids, In); Y(P, V)O₄:Eu; YTaO₄:Nb; YAlO₃:A (A=Pr, Tm, Er, Ce); YOCl:Yb,Er; LnPO₄:Ce,Tb (Ln=lanthanoids or mixtures of lanthanoids); LuVO₄:Eu; GdVO₄:Eu; Gd₂O₂S:Tb; GdMgB₆O₁₀:Ce,Tb; LaOBrTb; La₂O₂S:Tb; LaF₃:Nd, Ce; BaYb₂F₆:Eu; NaYF₄:Yb,Er; NaGdF₄:Yb,Er; NaLaF₄:Yb,Er; LaF₃:Yb,Er,Tm; BaYF₅:Yb,Er; Ga₂O₃:Dy; GaN:A (A=Pr, Eu, Er, Tm); Bi₄Ge₃O₁₂; LiNbO₃:Nd,Yb; LiNbO₃:Er; LiCaAlF₆:Ce; LiSrAlF₆:Ce; LiLuF₄:A (A=Pr, Tm, Er, Ce); GD₃Ga₅O₁₂:Tb; GD₃Ga₅O₁₂:Eu; Li₂B₄O₇:Mn; SiOₓ:Er,Al (O<x<2).

A second selection list is defined as follows:

YVO₄:Eu; YVO₄:Sm; YVO₄:Dy; LaPO₄:Eu; LaPO₄:Ce; LaPO₄:Ce,Tb; ZnS:Tb; ZnS:TbF₃; ZnS:Eu; ZnS:EuF₃; Y₂O₃:Eu; Y₂O₂S:Eu; Y₂SiO₅:Eu; SiO₂:Dy; SiO₂:Al; Y₂O₃:Tb; CdS:Mn; ZnS:Tb; ZnS:Ag; ZnS:Cu; Ca₃(PO₄)₂: Eu²⁺; Ca₃(PO₄)₂:Eu²⁺, Mn²⁺; Sr₂SiO₄:Eu²⁺; or BaAl₂O₄:Eu²⁺.

A third selection list for the doped nanoparticles is defined as follows:

MgF₂:Mn; ZnS:Mn; ZnS:Ag; ZnS:Cu; CaSiO₃:Ln; CaS:Ln; CaO:Ln; ZnS:Ln; Y₂O₃:Ln or MgF₂:Ln, where Ln is an element of the lanthanoids.

According to a further selection list, the colorant is at least one compound M^{I}₂O₃:M^{II}, where M^{I}=Y, Sc, La, Gd or Lu, and M^{II}=Eu, Pr, Ce, Nd, Tb, Dy, Ho, Er, Tm or Yb, or at least one compound M^{I}₂O₂S:M^{II} or at least one compound M^{III}S:M^{IV},M^{V},X, where M^{III}=Mg, Ca, Sr, Ba or Zn, and M^{IV}=Eu, Pr, Ce, Mn, Nd, Tb, Dy, Ho, Er, Tm or Yb, and M^{V}=Li, Na, K, Rb, and X=F, Cl, Br or I, or at least one compound M^{III}M^{VI}₂S₄:M^{II}, where M^{VI}=Al, Ga, In, Y, Se, La, Gd or Lu.

Colorants of this type are either commercially available or can be obtained by preparation processes known from the literature. Preferred preparation processes are described, in particular, in international patent applications WO 2002/20696 and WO 2004/096714, the corresponding disclosure content of which expressly belongs to the disclosure content of the present invention.

The colorant here can in accordance with the invention be introduced into the cavity structure in various ways.

Preference is given in accordance with the invention to a process for the preparation of a photonic material having regularly arranged cavities containing at least one colorant, which is characterised in that
a) template spheres are regularly arranged,
b) the sphere interstices are impregnated with a precursor of the wall material,
c) the wall material is formed and the template spheres are removed.

In a variant of the invention, it is preferred for the colorant to be present in the cavities of the photonic structure.

It has been found here that excessive degrees of filling of the cavities influence the photonic properties. It is therefore preferred in accordance with the invention for the cavities of the photonic material to be filled with the at least one colorant to the extent of at least 1% by vol. and at most 50% by vol., where the cavities are particularly preferably filled with the at least one colorant to the extent of at least 5% by vol. and at most 30% by vol.

For colorants having a density of about 4 g/cm³ which are preferably to be employed in accordance with the invention, the at least one colorant therefore makes up 5 to 75% by weight of the photonic material, where the at least one colorant preferably makes up 25 to 66% by weight of the photonic material.

In a preferred process variant, the colorant can be introduced into the cavities after removal of the template spheres. This is achieved, for example, by the photonic material having regularly arranged cavities being infiltrated with a colorant dispersion or a dispersion of colorant precursors, and the dispersion medium subsequently being removed.

The nanoscale colorants can be infiltrated into the inverse opals described above if the particle size of the colorant particles is smaller than the diameter of the apertures between the cavities of the inverse opals. In a preferred embodiment of the present invention, the nanoscale phosphor particles before the infiltration are in substantially agglomerate-free dispersed form in a liquid, preferably water or another volatile solvent.

Furthermore, it is sensible in the infiltration method to ensure complete filling of the cavities of the inverse opal with the suspension liquid. This is achieved, for example, using the following method:

The colorant dispersion is added to the inverse opal material, and the suspension is evacuated in order to remove the air included in the cavities of the inverse opal. The suspension is then aerated in order to fill the cavities completely with the nanophosphor suspension. The infiltrated particles are separated off from the excess nanophosphor suspension via a membrane filter and washed.

In another variant of the process according to the invention for the preparation of a photonic material, at least one colorant or colorant precursor is introduced into the template spheres before step a). During decomposition of the precursor cores, the colorant particles then remain in the resultant cavities. In this process variant, the size of the colorant particles is limited only by the size of the template spheres.

In a further variant of the invention, it is preferred for the colorant to be present in the wall of the photonic material.

In a corresponding preparation process, the colorant particles are either dispersed in the precursor preparation or a colorant dispersion is mixed with the precursor preparation before or during the impregnation of the cavities of the template structure.

According to the general object of the present invention, the present invention furthermore relates to the use of at least one photonic material according to the invention as phosphor system in an illuminant.

The photonic material here can particularly advantageously be employed for broadening the spectrum of an illuminant and thus in particular for generating white light.

An important aspect of the invention in this connection is the use of at least one photonic material according to the invention for increasing the emission of at least one colorant. Thus, for example, europium-doped yttrium vanadate cannot be employed alone in order to add red components to the blue light from AlInGaN emitters since the absorption of the blue light is not sufficient to stimulate the red emission. The emission can, as indicated in greater detail in the examples, be increased by means of the photonic material according to the invention comprising europium-doped yttrium vanadate.

In accordance with this object, the present invention furthermore relates to an illuminant comprising at least one light source, which is characterised in that it comprises at least one photonic material according to the invention.

In preferred embodiments of the present invention, the illuminant is a light-emitting diode (LED), an organic light-emitting diode (OLED), a polymeric light-emitting diode (PLED) or a fluorescent lamp.

For the application in light-emitting diodes which is preferred in accordance with the invention, it is particularly advantageous for radiation selected from the wavelength range from 250 to 500 nm to be stored in the photonic material, where the radiation is preferably selected from the wavelength range from 380 to 480 nm.

The blue to violet light-emitting diodes which are particularly suitable for the invention described here include semiconductor components based on GaN (InAlGaN). Suitable GaN semiconductor materials for the production of light-emitting components are described by the general formula InᵢGaⱼAlₖN, where 0≦i, 0≦j, 0≦k and i+j+k=1. These nitride semiconductor materials thus also include substances such as indium gallium nitride and GaN. These semiconductor materials may be doped with traces of further substances, for example in order to increase the intensity or adjust the colour of the emitted light. Laser diodes (LDs) are constructed in a similar manner from an arrangement of GaN layers. Processes for the production of LEDs and LDs are well known to specialists in this area.

Possible configurations in which a photonic structure can be coupled to a light-emitting diode or an arrangement of light-emitting diodes are LEDs mounted in a holding frame or on the surface.

Photonic structures of this type can be used in all configurations of illumination systems which comprise a primary radiation source, including, but not restricted to, discharge lamps, fluorescent lamps, LEDs, LDs (laser diodes), OLEDs and X-ray tubes. In this text, the term “radiation” encompasses radiation in the UV and IR region and in the visible region of the electromagnetic spectrum. Amongst the OLEDs, particular preference may be given to the use of PLEDs-OLEDs comprising polymeric electroluminescent compounds.

The construction of an illumination system of this type which has been produced and which comprises a radiation source and a phosphor (see FIG. 3) is described in detail below. The phosphor here is a photonic material according to the invention or a phosphor mixture comprising a photonic material according to the invention.

FIG. 3 depicts diagrammatically the appearance of a chip-like light-emitting diode whose coating comprises the phosphor. The invention comprises a chip-like light-emitting diode 1 as radiation source. The LED chip is mounted in a cup-shaped reflector held by an adjustment frame. The chip 1 is connected to a contact 6 by a wire 7 and directly to a second electrical contact 6′. A coating which comprises a phosphor according to the invention has been applied to the inner curvature of the reflector cup. The phosphors can either be employed separately from one another or as a mixture.

The coating typically comprises a polymer for inclusion of the phosphor or phosphor mixture according to the invention. This should be implemented in such a way that the phosphor or phosphor mixture is very stable to the inclusion material. The polymer is preferably optically clear in order to prevent significant light scattering. Some polymers which are suitable for the production of LED illumination systems are known in the LED industry.

In an embodiment according to the invention, the polymer is selected from a group of epoxy and silicone resins. Addition of the phosphor mixture to a liquid polymer precursor enables an inclusion to be achieved. For example, the phosphor mixture may be a granulated powder. On addition of the phosphor particles to the liquid polymer precursor, a suspension forms.

During the polymerisation, the phosphor mixture is spatially immobilised by the inclusion material. In an embodiment according to the invention, both the phosphor and also the LED cube are surrounded by the polymer.

The transparent coating may comprise light-scattering particles, advantageously so-called diffusers. Examples of such diffusers are mineral fillers, particularly CaF₂, TiO₂, SiO₂, CaCO₃ or BaSO₄ or organic pigments. These substances can easily be added to the resins mentioned.

In operation, electrical energy is supplied to the cube for activation. After activation, the cube emits primary light, i.e., for example, blue light. A part of this emitted primary light is partially or completely absorbed by the phosphor in the coating. After absorption of the primary light, the phosphor then itself emits converted secondary light, i.e. light having a longer-wavelength emission maximum, especially amber-coloured with a sufficiently broad emission band (particularly having a significant red component). The unabsorbed radiation component of the emitted primary light passes through the luminescent layer and leaves it together with the secondary light. The inclusion material orients the unabsorbed primary light and the secondary light roughly in such a way that the resultant radiation is able to exit the component. The resultant radiation is therefore composed of primary light emitted by the cube and the secondary light emitted by the luminescent layer.

The colour temperature or colour value of the resultant light from an illumination system according to the invention depends on the spectral distribution and intensity of the secondary light compared with the primary light. Firstly, the colour temperature or colour value of the primary light can be varied through the choice of a suitable light-emitting diode. Secondly, the colour temperature or colour value of the secondary light can be varied through the choice of a suitable, specific phosphor mixture in the photonic structure.

For example, a green phosphor may additionally be necessary in order to obtain a light source whose emission is perceived as white by an observer. In this case, a second phosphor can be added. Otherwise, a resin-immobilised luminescent pigment can be added.

Light-emitting diodes are frequently applied to insulating substrates, such as sapphire, and both contacts are located on the same side of the component. The components can then be mounted in such a way that the light leaves the component either through the contacts (epitaxy-up design) or through the surface opposite the contacts (flip-chip design).

In operation, the wavelength of a part of the light emitted by the light-emitting diode is modified by the photonic structure, while the remainder of the emitted light is superimposed on the wavelength-converted light to give white or coloured light.

As a consequence of an aspect according to the invention, the light emitted by an illumination system comprising a radiation source, preferably a light-emitting diode, and a photonic material according to the invention can have a spectral distribution which enables it to appear as white light.

The most popular conventional LEDs comprising converter phosphor and having white emission consist of a blue light-emitting LED chip, which is coated with a phosphor which converts a part of the blue light into light of the complementary colour, for example a yellow to amber emission. Together, the emitted blue and yellow light give white light.

White light-emitting LEDs, which comprise a UV light-emitting chip and phosphors, which convert the UV radiation into visible light are likewise known. The emission bands of two or more phosphors must typically overlap in order to generate white light.

In operation, a part of the blue primary light emitted by the LED passes through the photonic structure without hitting phosphor particles. Another part of the blue primary radiation emitted by the LED hits the activator ions of the photonic structure, which then emit red light. The wavelength of a part of the 460 nm emission of an AlInGaN light-emitting diode is therefore shifted into the red spectral region. Together with the yellow to amber emission described above, white light with an adjustable colour temperature is then obtained.

A second embodiment according to the invention of a white light-emitting system with even better colour mixing comprises a blue-emitting LED and an amber- and red-emitting photonic structure together with a second phosphor as additional luminescence converter, preferably a broad-band green emitter.

The following table shows some useful additional phosphors and their optical properties. The colour values x and y here are the colour coordinates in accordance with the “CIE diagram 1931” chromaticity diagram.

| Composition | λₘₐₓ [nm] | Colour value x, y |
|---|---|---|
| (Ba₁₋ₓSrₓ)₂SiO₄: Eu | 523 | 0.272, 0.640 |
| SrGa₂S₄: Eu | 535 | 0.270, 0.686 |
| SrSi₂N₂O₂: Eu | 541 | 0.356, 0.606 |
| SrS: Eu | 610 | 0.627, 0.372 |
| (Sr_{1-x-y}CaₓBa_{y})₂Si₅N₈: Eu | 615 | 0.615, 0.384 |
| (Sr_{1-x-y}CaₓBa_{y})₂Si₅₋ₐAlₐN₈₋ₐOₐ: Eu | 615-650 | * |
| CaS: Eu | 655 | 0.700, 0.303 |
| (Sr₁₋ₓCaₓ)S: Eu | 610-655 | * |

* The colour value depends on the value of x.

According to another aspect of the invention, the light emitted by the illumination system, which comprises a radiation source and a photonic structure having amber to red emission, can have a spectral distribution which enables it to appear as amber and red light.

The emission colour of an LED system is highly dependent on the thickness of the photonic structure. In the case of large thickness, only a relatively small proportion of the blue primary emission from the LED is able to pass through the photonic structure. The emission of the system as a whole will then appear amber and red, since the yellow and red colour of the secondary light of the photonic structure dominates. The thickness of the photonic structure is therefore a critical influencing parameter for the colour impression of the emission as a whole.

A photonic structure comprising one of the colorants described above is particularly suitable as yellow and red component, which is stimulated by the blue primary radiation from a light source, for example a blue-emitting light-emitting diode.

Light-emitting components comprising phosphors for colour conversion which emit in the yellow and red region of the electromagnetic spectrum are therefore accessible.

Even without further comments, it is assumed that a person skilled in the art will be able to utilise the above description in the broadest scope. The preferred embodiments should therefore merely be regarded as descriptive disclosure which is absolutely not limiting in any way. The complete disclosure content of all applications and publications mentioned above and below is incorporated into this application by way of reference. The following examples are intended to illustrate the present invention. However, they should in no way be regarded as limiting. All compounds or components which can be used in the preparations are either known and commercially available or can be synthesised by known methods.

### EXAMPLES

### Example 1

### Production of a Photonic Cavity Structure with SiO₂ Wall and Stop Band in the Blue-Green Region of the Spectrum

Firstly, monodisperse PMMA nanospheres are produced. This is carried out with the aid of an emulsifier-free, aqueous emulsion polymerisation. To this end, a 2 l jacketed stirred reactor with anchor stirrer (stirrer speed 300 rpm) and reflux condenser is charged with 1260 ml of deionised water and 236 ml of methyl methacrylate, and the mixture is heated to 80° C. A weak stream of nitrogen, which is able to escape via an overpressure valve on the reflux condenser, is passed into the mixture for 1 h before 1.18 g of azodiisobutyramidine dihydrochloride as free-radical initiator are added. The formation of latex particles is evident from the clouding which immediately sets in. The polymerisation reaction is followed thermally, with a slight increase in the temperature being observed due to the enthalpy of reaction. After two hours, the temperature has re-stabilised at 80° C., indicating the end of the reaction. After cooling, the mixture is filtered through glass wool. Investigation of the dried dispersion by SEM shows uniform, spherical particles having an average diameter of 317 nm.

These spheres are used as template for the production of the photonic structure. To this end, 10 g of dried PMMA spheres are slurried in deioniced water and filtered off with suction via a Büchner funnel.

Variant: alternatively, the dispersion resulting from the emulsion polymerisation is spun or centrifuged directly in order to allow the particles to settle in an ordered manner, the supernatant liquid is removed, and the residue is processed further as described below.

The filter cake is wetted with 10 ml of a precursor solution consisting of 3 ml of ethanol, 4 ml of tetraethoxysilane, 0.7 ml of conc. HCl in 2 ml of deionised water, while maintaining the suction vacuum. After the suction vacuum has been switched off, the filter cake is dried for 1 h and then calcined in air in a corundum container in a tubular furnace. The calcination is carried out in accordance with the following temperature ramps:

a) from RT to a temperature of 100° C. in 2 h, hold at 100° C. for 2 h,
b) from a temperature of 100° C. to 350° C. in 4 h, hold at 350° C. for 2 h,
c) from a temperature of 350° C. to 550° C. in 3 h,
d) the material is treated at 550° C. for a further 14 days, subsequently
e) cooled from 550° C. to RT at 10° C./min (from 550° C. to RT in 1 h).

The resultant inverse opal powder has an average pore diameter of about 300 nm (cf. FIG. 1). The powder particles of the inverse opal have an irregular shape with a spherical equivalent diameter of 100 to 300 μm. The cavities have a diameter of 300 nm and are connected to one another by 60 nm apertures.

### Example 2

### Infiltration of Nanoscale Phosphor Particles into a Photonic Cavity Structure

### Example 2a

### Infiltration of Y₂O₃:Eu into a Photonic Cavity Structure with SiO₂ Wall

An agglomerate-free suspension of nanoscale Y₂O₃:Eu particles in water (Nanosolutions; average particle size=10 nm) is diluted to a concentration of 10 mg/ml. A volume of 1 ml of this suspension is degassed by repeated evacuation and aeration. 10 mg of particles having a photonic cavity structune with walls of SiO₂ (cf. Example 1) are then added. The suspension is evacuated in order to remove the air included in the cavities of the inverse opal. The suspension is then aerated in order completely to fill the cavities with the nanophosphor suspension. The infiltrated particles are separated off from the excess nanophosphor suspension via a membrane filter having a pore diameter of 5 μm and washed a number of times on the filter with several milliliters of water. The washed inverse particles are firstly dried under gentle conditions at 60° C. and subsequently dried at 150° C. in order completely to remove the water included in the cavities.

An inverse opal powder comprising 3.8% by weight of nanoscale Y₂O₃:Eu phosphor particles which are distributed in the cavities of the inverse opal is obtained.

### Example 2b

### Infiltration of YVO₄:Eu into a Photonic Cavity Structure with SiO₂ Wall

An aqueous suspension of nanoscale YVO₄:Eu (REN X Red; Nanosolutions; average particle size=10 nm) in water is diluted to a concentration of 10 mg/ml. 2 ml of the dilute suspension are filtered through a disposable membrane filter having a pore diameter of 0.2 μm in order to remove agglomerates. The suspension is degassed by repeated evacuation and aeration. 20 mg of particles having a photonic cavity structure with walls of SiO₂ (cf. Example 1) are then added. The suspension is evacuated in order to remove the air included in the cavities of the inverse opal. The suspension is then aerated in order completely to fill the cavities with the nanophosphor suspension. The infiltrated inverse opal pieces are separated off from the excess nanophosphor suspension via a membrane filter having a pore diameter of 5 μm and washed a number of times on the filter with several milliliters of water. The washed inverse opal pieces are firstly dried under gentle conditions at 60° C. and subsequently dried at 150° C. in order completely to remove the water included in the cavities of the inverse opal. An inverse opal powder comprising 7.0% by weight of nanoscale YVO₄:Eu phosphor particles which are distributed in the cavities of the photonic structure is obtained.

FIG. 2 shows the excitation spectrum of YVO₄:Eu in an Aerosil matrix (Degussa) (=reference) compared with the excitation spectrum of the YVO₄:Eu-doped inverse opal (inverse opal matrix). The photoluminescence in a.u. is plotted on the y axis. The samples were selected so that the phosphor concentration is identical in each case. The pulverulent products were excited with variable wavelength and the photoluminescence intensity of the red peak around 610 nm that resulted was detected (=excitation spectrum).

On comparison of the two spectra, the lower intensity of the “reference” curve at wavelengths in the region greater than 350 nm is evident. It is assumed that the sample consisting of phosphor in the inverse opal matrix exhibits the higher photoluminescence intensity here since the excitation light is in resonance with the inverse opal, i.e. its wavelength corresponds to the stop bands of the inverse opal.

### Example 2c

### Multiple Infiltration of YVO₄:Eu

An aqueous suspension of nanoscale YVO₄:Eu (REN X Red; Nanosolutions; average particle size=10 nm) in water is diluted to a concentration of 10 mg/ml. 2 ml of the dilute suspension are filtered through a disposable membrane filter having a pore diameter of 0.2 μm in order to remove agglomerates. The suspension is degassed by repeated evacuation and aeration. 20 mg of particles having a photonic cavity structure with walls of SiO₂ (cf. Example 1) are then added. The suspension is evacuated in order to remove the air included in the cavities of the inverse opal. The suspension is then aerated in order completely to fill the cavities with the nanophosphor suspension. The infiltrated particles are separated off from the excess nanophosphor suspension via a membrane filter having a pore diameter of 5 μm and washed a number of times on the filter with several milliliters of water. The washed inverse opal pieces are firstly dried under gentle conditions at 60° C. and subsequently dried at 150° C. in order completely to remove the water included in the cavities of the inverse opal. The inverse opal pieces dried in this way are mixed a further twice with YVO₄:Eu phosphor suspension and worked up by the method described above. The concentration of nanophosphors in the cavities of the inverse opal can thereby be increased to 20.3% by weight of YVO₄:Eu.

### Example 3

### Preparation of a Phosphor in a Prespecified Inverse Opal Structure

### Example 3a

### Preparation of a Y₂O₃:Eu Coating

A solution of 7.582 g of YCl₃*6H₂O and 0.549 g of EuCl₃*6H₂O in 1 l of distilled water is prepared (solution A). 1.8 g of urea are dissolved in 50 ml of solution A (solution B). 40 g of a cavity structure from Example 1 are then impregnated with solution B and heated at 95° C. for 2 h in a closed vessel. The coated inverse opal is then transferred onto a filter and washed with dist. water until free from chloride and dried at 100° C. The powder is calcined for 2 h at 400-700° C. in a vacuum oven.

### Example 3b

### Preparation of a Gd₂O₂S:Tb Coating

A solution of 9.290 g of GdCl₃*6H₂O and 0.010 g of TbCl₃*6H₂O in 1 l of distilled water is prepared (solution A). 1.8 g of urea are dissolved in 50 ml of solution A (solution B). 40 g of an inv. opal from Example 1 are then impregnated with solution B and heated at 95° C. for 2 h in a closed vessel. The coated inverse opal is then transferred onto a filter and washed with dist. water until free from chloride and dried at 100° C. The powder is then heated at 750° C. for 4 h in a sulfur-saturated argon atmosphere.

### Example 3c

### Preparation of a Cas:Ce Coating

5 g of Ca(NO₃)₂*4H₂O and 9.2 mg of Ce(NO₃)₃*6H₂O are dissolved in 100 ml of ethylene glycol and heated under reflux for 2 h under argon. 100 g of the inverse opal from Example 1 are then impregnated with this solution, and the suspension is dried at 80° C. under reduced pressure. The powder is then heated at 650° C. for 4 h in a stream of H₂S.

### Example 3d

### Preparation of an SrGa₂S₄:Eu Coating

7 g of Sr(NO₃)₂*6H₂O, 13.343 g of Ga(NO₃)₃*6H₂O and 82 mg of Eu(NO₃)₃*6H₂O are dissolved in 160 ml of ethylene glycol and heated under reflux for 4 h under argon. 100 g of the inverse opal are then impregnated with this solution, and the suspension is dried at 80° C. under reduced pressure. The powder is then heated at 700° C. for 4 h in CS₂-saturated argon.

### Example 4

### Production of a Photonic Cavity Structure with SiO₂ Wall which Comprises Phosphors

100 ml of a precursor solution are prepared by mixing 80 g of ethanol, 10 g of tetraethoxysilane and 10 g of 2 molar aqueous hydrochloric acid (solution A). The solution is stirred overnight at room temperature. A suspension of nanoscale Y₂O₃:Eu phosphor particles in water is diluted to a concentration of 20 mg/ml (solution B). 9 ml of precursor solution A and 1 ml of nanophosphor suspension B are mixed.

As described in Example 1, PMMA spheres are used as template for the production of the photonic structure. To this end, 10 g of dried PMMA spheres are slurried in deionised water and filtered off with suction via a Büchner funnel. A regular PMMA sphere packing (=PMMA opal) forms. A few drops of the nanophosphor-containing precursor solution (A+B) are applied to the PMMA opal which is deposited on the membrane filter. Just sufficient of the nanophosphor-containing precursor solution is applied dropwise to completely fill the pore structure of the opal. The infiltrated latex opal is then dried at 50° C. on the membrane filter in an oven, and the pre-hydrolysed tetraethoxysilane hydrolyses and crosslinks completely at 80° C.

The infiltration with nanophosphor-containing precursor solution and the subsequent drying are repeated a number of times until the latex opal is completely filled and no longer takes up solution.

The completely filled opal is slowly heated in accordance with the programme shown below to a final temperature of 600° C. In the process, the hydrolysed silane is converted into SiO₂, and the PMMA particles are completely removed by pyrolysis. An inverse opal powder comprising SiO₂ is obtained. The SiO₂ structure comprises about 5% by weight of nanoscale Y₂O₃:Eu phosphor particles.

### Calcination Programme:

a) from RT to a temperature of 100° C. in 2 h, hold at 100° C. for 2 h,
b) from a temperature of 100° C. to 350° C. in 4 h, hold at 350° C. for 2 h,
c) from a temperature of 350° C. to 600° C. in 3 h, hold at 600° C. for 14 days,
e) cool from 600° C. to RT at 10° C./min (from 600° C. to RT in 1 h).

### Example 5

### Light-Emitting Diode Comprising a Photonic Cavity Structure

A formulation of a rare-earth phosphor in inverse opal (in each case in accordance with at least one of Examples 2-4) is finely ground (particle size 3-20 μm) and mixed with YAG:Ce (particle size 3-20 μm) in silicone or epoxy resin. This phosphor formulation is
A) either applied dropwise using a microdispenser directly to the AlInGaN chip provided with gold bonding wire on the upper side, or
B) the phosphor formulation is transferred into the reflector funnel containing the AlInGaN chip (FIG. 3), or
C) the phosphor formulation is introduced into the material of which the lens (lamp of the LED) consists, so that during manufacture of the lens the latter is homogeneously filled with the phosphor formulation, or
D) the phosphor formulation is applied subsequently to the surface of the lens of the LED.

### INDEX OF THE FIGURES

FIG. 1 shows an SEM photograph of the photonic cavity structure in accordance with Example 1.

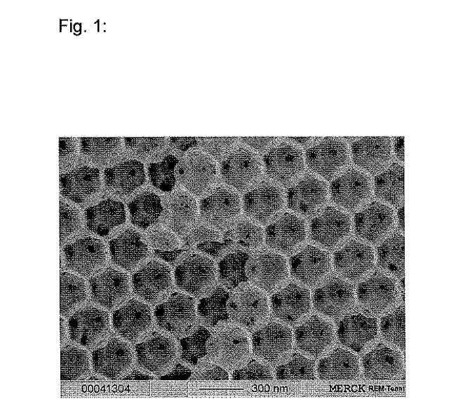

FIG. 2 shows the excitation spectrum of YVO₄:Eu in an Aerosil matrix (Degussa) (=reference) compared with the excitation spectrum of the YVO₄:Eu-doped inverse opal in accordance with Example 2b (inverse opal matrix). The photoluminescence in a.u. is plotted on the y axis. The samples were selected so that the phosphor concentration is identical in each case. The pulverulent products were excited with variable wavelength and the photoluminescence intensity of the red peak around 610 nm that resulted was detected (=excitation spectrum).

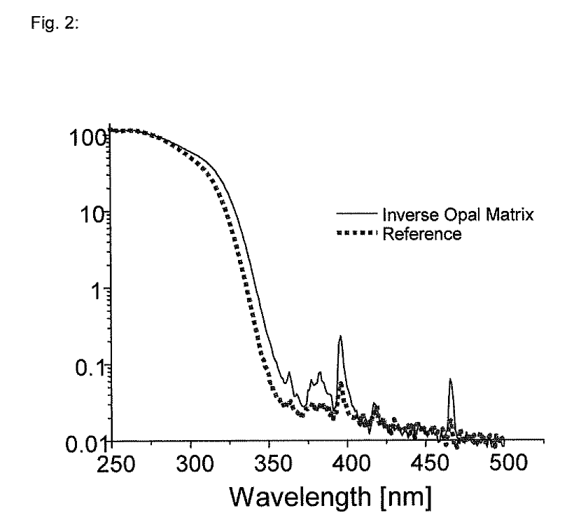

FIG. 3 shows the diagrammatic depiction of a light-emitting diode having a phosphor-containing coating. The component comprises a chip-like light-emitting diode (LED) 1 as radiation source. The light-emitting diode is mounted in a cup-shaped reflector held by an adjustment frame 2. The chip 1 is connected to a first contact 6 via a flat cable 7 and directly to a second electrical contact 6′. A coating which comprises a photonic structure according to the invention has been applied to the inner curvature of the reflector cup. The phosphors are either employed separately from one another or as a mixture (list of part numbers: 1 light-emitting diode, 2 reflector, 3 resin, 4 photonic structure, 5 diffuser, 6 electrodes, 7 flat cable).

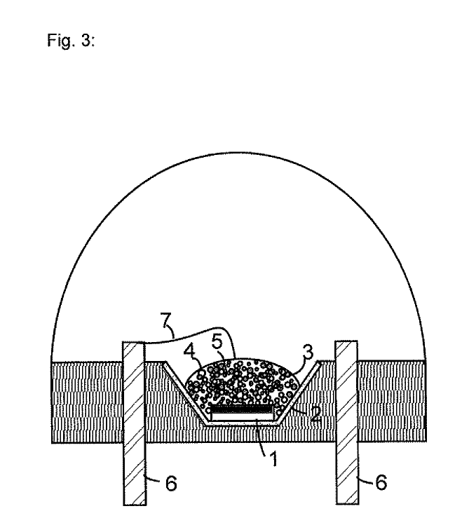

1. Photonic material having regularly arranged cavities containing at least one colorant, where the wall material of the photonic material has dielectric properties and as such is essentially non-absorbent for the wavelength of an absorption band of the respective colorant and is essentially transparent for the wavelength of a colorant emission which can be stimulated by the absorption wavelength, and the cavities are shaped in such a way that radiation having the wavelength of the weak absorption band of the colorant is stored in the photonic material.

2. Photonic material according to claim 1, characterised in that the colorant is present in the cavities of the photonic material.

3. Photonic material according to claim 1, characterised in that the colorant is present in the wall of the photonic material.

4. Photonic material according to claim 1, characterised in that the wall material of the photonic material allows at least 95%, preferably at least 97%, of the radiation having the wavelength of the weak absorption band of the colorant to pass through.

5. Photonic material according to claim 1, characterised in that radiation selected from the wavelength range from 250 to 500 nm is stored in the photonic material, where the radiation is preferably selected from the wavelength range from 380 to 480 nm and particularly preferably from an indium gallium nitride, in particular of the formula InᵢGaⱼAlₖN, where 0≦i, 0≦j, 0≦k, and i+j+k=1.

6. Photonic material according to claim 1, characterised in that the colorant is an emitter for radiation in the range from 550 to 700 nm, preferably a rare-earth compound doped with europium, samarium, terbium or praseodymium, preferably with triply positively charged europium ions.

7. Photonic material according to claim 1, characterised in that the colorant is at least one compound M^{I}₂O₃:M^{II}, where M^{I}=Y, Sc, La, Gd or Lu and M^{II}=Eu, Pr, Ce, Nd, Tb, Dy, Ho, Er, Tm or Yb, or at least one compound M^{I}₂O₂S:M^{II} or at least one compound M^{III}S:M^{IV},A,X, where M^{III}=Mg, Ca, Sr, Ba or Zn and M^{IV}=Eu, Pr, Ce, Mn, Nd, Tb, Dy, Ho, Er, Tm or Yb and A=Li, Na, K or Rb and X=F, Cl, Br or I, or at least one compound M^{III}M^{V}₂S₄:M^{II}, where M^{V}=Al, Ga, In, Y, Sc, La, Gd or Lu.

8. Photonic material according to claim 6, characterised in that the rare-earth compound is a compound selected from the group of the phosphates, halophosphates, arsenates, sulfates, borates, silicates, aluminates, gallates, germanates, oxides, vanadates, niobates, tantalates, tungstates, molybdates, alkali metal halogenates, halides, nitrides, sulfides, selenides, sulfoselenides and oxysulfides.

9. Photonic material according to claim 1, characterised in that the colorant is in nanoparticulate form, preferably having an average particle size of less than 50 nm (hydraulic diameter determined by means of dynamic light scattering).

10. Photonic material according to claim 1, characterised in that the wall of the photonic material essentially consists of an oxide or mixed oxide of silicon, titanium, zirconium and/or aluminium, preferably of silicon dioxide.

11. Photonic material according to claim 1, characterised in that the cavities of the photonic material have a diameter in the range from 200 to 400 nm.

12. Photonic material according to claim 1, characterised in that the cavities of the photonic material are filled with the at least one colorant to the extent of at least 1% by vol. and at most 50% by vol., where the cavities are particularly preferably filled with the at least one colorant to the extent of at least 5% by vol. and at most 30% by vol.

13. Photonic material according to claim 1, characterised in that the at least one colorant makes up 5 to 75% by weight of the photonic material, where the at least one colorant preferably makes up 25 to 66% by weight of the photonic material.

14. A phosphor system in an illuminant comprising a photonic material of claim 1.

15. A method for broadening the spectrum of an illuminant, preferably for generating white light comprising employing in said illuminant of at least one photonic material of claim 1.

16. A method for increasing the emission of a colorant comprising employing therein at least one photonic material according to claim 1.

17. Illuminant comprising at least one light source, characterised in that it comprises at least one photonic material according to claim 1.

18. Illuminant according to claim 17, characterised in that the light source is an indium aluminium gallium nitride, in particular of the formula InᵢGaⱼAlₖN, where 0≦i, 0≦j, 0≦k, and i+j+k=1.

19. Illuminant according to claim 1, characterised in that the illuminant is a light-emitting diode (LED), an organic light-emitting diode (OLED), a polymeric light-emitting diode (PLED) or a fluorescent lamp.

20. Process for the preparation of a photonic material having regularly arranged cavities containing at least one colorant, characterised in that
a. template spheres are regularly arranged,
b. the sphere interstices are impregnated with a precursor of the wall material,
c. the wall material is formed and the template spheres are removed.

21. Process for the preparation of a photonic material according to claim 20, characterised in that the colorant is introduced into the cavities after removal of the template spheres.

22. Process for the preparation of a photonic material according to claim 21, characterised in that the photonic material having regularly arranged cavities is infiltrated with a colorant dispersion or a dispersion of colorant precursors, and the dispersion medium is subsequently removed.

23. Process for the preparation of a photonic material according to claim 22, characterised in that at least one colorant or colorant precursor is introduced into the template spheres before step a).
